(19) United States
(12) Patent Application Publication
(10) Pub. No.: US 2017/0052027 A1
(43) Pub. Date: Feb. 23, 2017

(54) VIBRATION ANGULAR VELOCITY SENSOR

(71) Applicant: DENSO CORPORATION, Kariya-city, Aichi-pref. (JP)

(72) Inventors: Tomoya JOMORI, Kariya-city (JP); Minekazu SAKAI, Kariya-city (JP)

(21) Appl. No.: 15/307,845

(22) PCT Filed: Jun. 2, 2015
(86) PCT No.: PCT/JP2015/002784

§ 371 Date: Oct. 31, 2016

(30) Foreign Application Priority Data
Jun. 12, 2014 (JP) 2014-121692
May 13, 2015 (JP) 2015-098407

(51) Int. Cl. G01C 19/5747; B81B 3/00; H01L 41/113

(52) U.S. Cl. CPC G01C 19/5747; H01L 41/1132; B81B 3/0021; B81B 2201/0242; B81B 2203/0118; B81B 2203/0163

(57) ABSTRACT

A vibration angular velocity sensor includes a fixed portion, a movable portion, a beam portion, and an anti-vibration spring structure. The movable portion has driving-detection weights. The beam portion has detection beams, support members, and driving beams, and has a frame structure formed of the driving beams, the support members, and the driving-detection weights. The anti-vibration spring structure is disposed between the detection beams and the fixed portion and is deformable along a first axis and a second axis. The vibration angular velocity sensor causes the driving-detection weights disposed on both sides of the fixed portion to undergo driving vibrations in directions opposite to each other along the first axis about the fixed portion and detects an angular velocity based on a fact that the driving-detection weights vibrate also along the second axis upon application of the angular velocity.

### CROSS REFERENCE TO RELATED APPLICATION

This application is based on Japanese Patent Application No. 2014-121692 filed on Jun. 12, 2014 and Japanese Patent Application No. 2015-098407 filed on May 13, 2015, the disclosure of which is incorporated herein by reference.

### TECHNICAL FIELD

The present disclosure relates to a vibration angular velocity sensor.

### BACKGROUND ART

A vibration angular velocity sensor in the related art is proposed in Patent Literature 1. The vibration angular velocity sensor includes detection beams extended on both sides in a y-axis direction with a fixed portion as a center and driving beams extended parallel to the detection beams via support portions which extend from the fixed portion in an x-axis direction. Detection weights are disposed to tip ends of the respective detection beams on an opposite side from the fixed portion and driving weights are disposed to tip ends of the respective driving beams on an opposite side from connection portions to the support portions.

The vibration angular velocity sensor configured as above operates to cause the driving weights located on both sides of the detection weights to undergo driving vibrations symmetrically in the x-axis direction about the detection weights. When an angular velocity is applied during such an operation, the detection beams undergo displacement in a rotation direction about the fixed portion. The vibration angular velocity sensor detects the angular velocity by detecting the displacement of the detection beams using detection elements.

In the vibration angular velocity sensor as above, basically, the driving weights vibrate in the x-axis direction in the absence of an angular velocity and vibration weights and the detection weights vibrate also in the y-axis direction upon application of an angular velocity due to a force in the rotation direction about the fixed portion. In short, in the vibration angular velocity sensor, directions of driving vibrations of the driving weights and detection vibrations of the detection weights are on an x-y plane.

However, unwanted vibrations in a z-axis direction may occur for some reason, for example, depending on presence or absence of vibrations (vehicle vibrations or the like) transmitted from a portion other than the vibration angular velocity sensor, misalignment of an axis orientation, asymmetrical machining, and a crystal fault. More specifically, the vibration angular velocity sensor has a large number of unwanted vibration modes, for example, a mode in which the detection weights are not undergoing unwanted vibrations while the driving weights are undergoing unwanted vibrations and a mode in which both of the detection weights and the driving weights are undergoing unwanted vibrations. An unwanted signal attributed to such unwanted vibrations is included in a detection signal outputted from the detection elements. Hence, the vibration angular velocity sensor fails to detect an angular velocity accurately. It is therefore crucial to reduce unwanted vibration modes by restricting unwanted vibrations in order to increase detection accuracy of an angular velocity.

### PRIOR ART LITERATURES

### Patent Literature

[Patent Literature 1] JP 2011-59040 A

### SUMMARY OF INVENTION

In view of the foregoing difficulties, it is an object of the present disclosure to provide a vibration angular velocity sensor capable of enhancing detection accuracy by restricting unwanted vibrations of a movable portion.

A vibration angular velocity sensor according to a first aspect of the present disclosure includes: a fixed portion fixed to a substrate; a movable portion having driving-detection weights disposed on both sides of a first axis along one direction on a plane of the substrate with the fixed portion as a center to serve as both a driving weight and a detection weight; a beam portion having detection beams supported to the fixed portion and extended on both sides of a second axis perpendicular to the first axis on the plane of the substrate with the fixed portion as a center, support members disposed to tip ends of the detection beams on an opposite side from the fixed portion so as to cross the detection beams, and driving beams supported to the support members and disposed on both sides of the first axis with the detection beams in between to support the driving-detection weights at both ends, and having a frame structure formed of the driving beams, the support members, and the driving-detection weights. The vibration angular velocity sensor causes the driving-detection weights disposed on the both sides of the fixed portion to undergo driving vibrations in directions opposite to each other along the first axis about the fixed portion and detects an angular velocity based on a fact that the driving-detection weights vibrate also along the second axis on the plane of the substrate upon application of the angular velocity. In the above-described configuration, an anti-vibration spring structure that is deformable along the first axis and the second axis is disposed between the detection beams and the fixed portion.

In the manner as above, the anti-vibration spring structure is provided to portions connecting the fixed portion to the movable portion and the beam portion. Owing to the structure as above, in the case of an unwanted vibration mode in which a resonance frequency is lower than resonance frequencies of driving vibrations and detection vibrations (a driving frequency and a detection frequency, respectively) induced by an external impact, the anti-vibration spring structure mainly deforms rather than the beam portion, and deformation of the beam portion can be restricted. Consequently, detection accuracy can be enhanced and unwanted vibration modes that deteriorate detection accuracy can be reduced.

When the anti-vibration spring structure is disposed at a center support portion of the movable portion and the beam portion which form a frame structure, displacement of connection portions between the detection beams and the anti-vibration spring structure is increased by displacement of the anti-vibration spring structure in comparison with a case where the detection beams are directly connected to the fixed portion. Hence, when an angular velocity is applied, the angular velocity can be detected by a vibration detection portion based on larger deformation of the detection beams. Consequently, detection accuracy can be enhanced further.

A vibration angular velocity sensor according to a second aspect of the present disclosure includes: a fixed portion fixed to a substrate; a movable portion having driving weights disposed on both sides of a first axis along one direction on a plane of the substrate with the fixed portion as a center and detection weights disposed on both sides of a second axis perpendicular to the first axis on the plane of the substrate; a beam portion having driving beams disposed on both sides of the first axis with the fixed portion as a center to support the driving weights at both ends, support members disposed on both sides of the second axis and to which the driving beams are connected, and detection beams connected to center positions of the supporting members and supporting the detection weights, and having a frame structure formed of the support members, the driving beams, and the driving weights; and an anti-vibration spring structure connecting the beam portion and the fixed portion and being deformable along the first axis and the second axis.

Even when the vibration angular velocity sensor has the structure as above, effects same as the effects of the vibration angular velocity sensor of the first aspect can be obtained.

### BRIEF DESCRIPTION OF DRAWINGS

The above and other objects, features and advantages of the present disclosure will become more apparent from the following detailed description made with reference to the accompanying drawings. In the drawings:

FIG. 1 is a top view of a vibration angular velocity sensor according to a first embodiment of the present disclosure;

FIG. 2 is a perspective view of the vibration-type angular velocity sensor shown in FIG. 1;

FIG. 3 is a sectional view taken along the line III-Ill of FIG. 1;

FIG. 4 is a sectional view taken along the line IV-IV of FIG. 1;

FIG. 5 is a top view of the vibration angular velocity sensor of FIG. 1 during driving vibrations;

FIG. 6 is a top view of the vibration angular velocity sensor of FIG. 1 when an angular velocity is applied;

FIG. 7 is a perspective view of one example of an unwanted vibration mode;

FIG. 8 is a perspective view of another example of the unwanted vibration mode;

FIG. 9 is a top view of a vibration angular velocity sensor according to a second embodiment of the present disclosure; and

FIG. 10 is a top view of a vibration angular velocity sensor used to describe a modification of the second embodiment.

### DESCRIPTION OF EMBODIMENTS

Hereinafter, embodiments of the present disclosure will be described according to the drawings. Respective embodiments will be described below by labeling same or equivalent portions with same reference numerals.

### First Embodiment

A first embodiment of the present disclosure will be described. A vibration angular velocity sensor (gyro sensor) described in the present embodiment is a sensor detecting an angular velocity as a physical amount and used to detect, for example, a rotational angular velocity about a center line parallel to a top-bottom direction of a vehicle. However, it goes without saying that the vibration angular velocity sensor is also applicable to objects other than a vehicle.

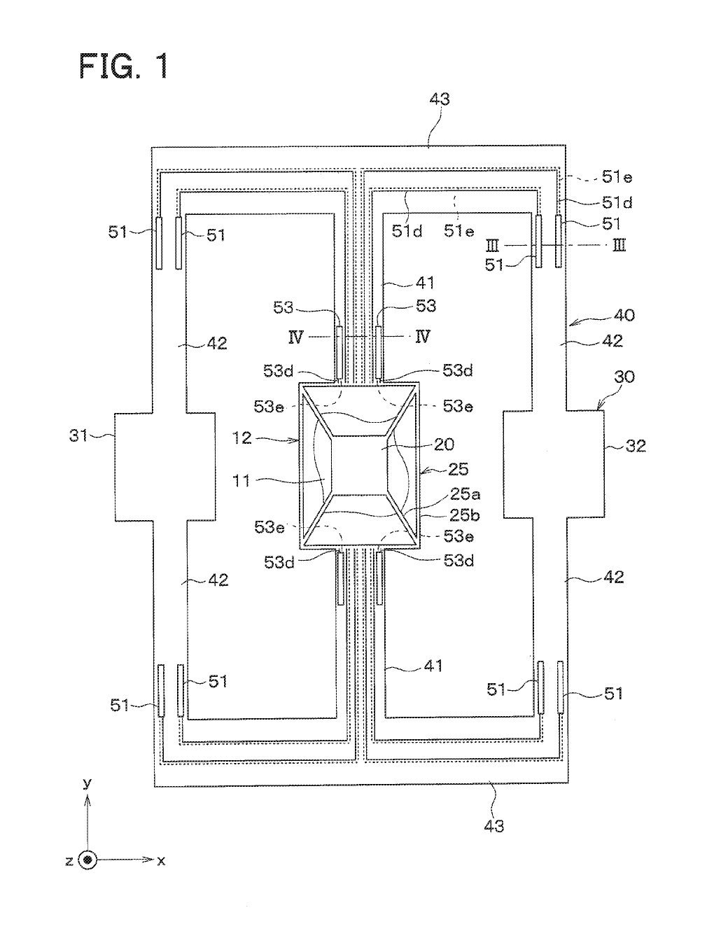

In the following, the vibration angular velocity sensor of the present embodiment will be described with reference to FIG. 1 through FIG. 8.

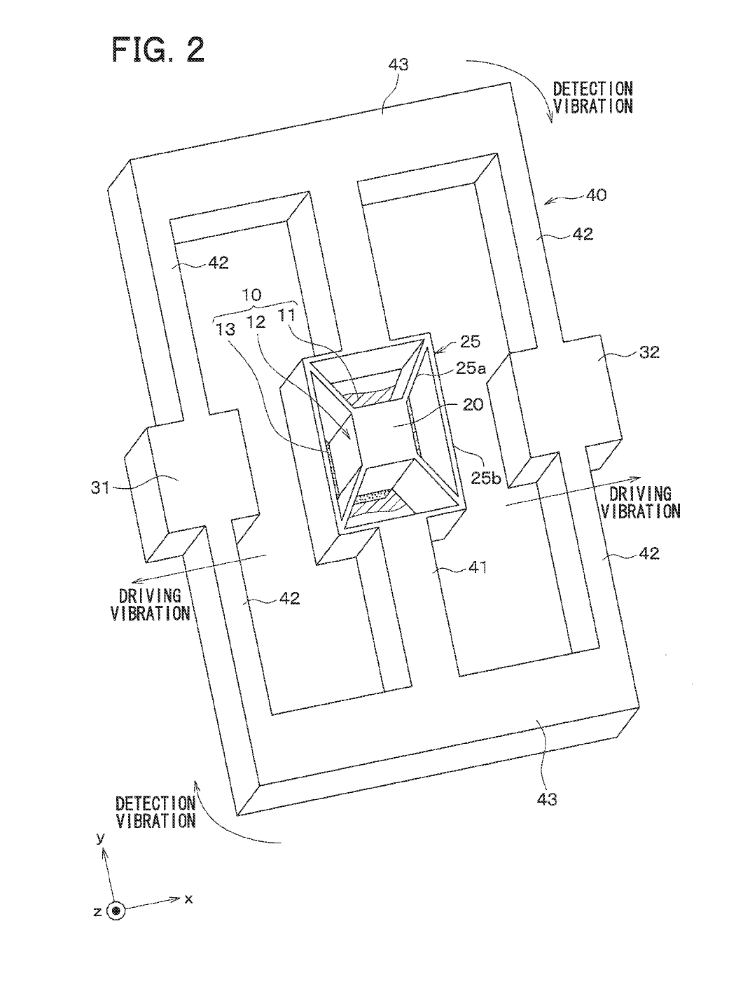

The vibration angular velocity sensor is installed to a vehicle in such a manner that an x-y plane of FIG. 1 faces a horizontal direction of the vehicle and a z-axis direction coincides with the top-bottom direction of the vehicle. The vibration angular velocity sensor is formed using a substrate 10 having a plate shape. In the present embodiment, the substrate 10 is an SOI (silicon-on-insulator) substrate having a structure in which an embedded oxide film 13 serving as a sacrificial layer is sandwiched between a support substrate 11 and a semiconductor layer 12. One direction of a plane of the substrate 10 is given as an x axis, a direction perpendicular to the x axis on the plane is given as a y axis, and a direction normal to the plane and perpendicular to both of the x axis and the y axis is given as a z axis. The plane of the substrate 10 is a plane parallel to the x-y plane. The x axis is referred to also as a first axis and the y axis is referred to also as a second axis. The vibration angular velocity sensor is formed by using the substrate 10 as above. The vibration angular velocity sensor is formed as is shown in FIG. 2 by, for example, etching a pattern of a sensor structure on a side of the semiconductor layer 12 and releasing a part of the sensor structure by removing the embedded oxide film 13 partially. In the drawing, the support substrate 11 is shown simply. However, the support substrate 11 is formed in a flat plate shape in practice. Although FIG. 2 is not a sectional view, the support substrate 11 and the embedded oxide film 13 are shaded for ease of visual understanding.

The semiconductor layer 12 is patterned into a fixed portion 20, an anti-vibration spring structure 25, a movable portion 30, and a beam portion 40. As is shown in FIG. 2, the fixed portion 20 is not released from the support substrate 11 because the embedded oxide film 13 on a back surface is left at least partially. Hence, the fixed portion 20 is fixed to the support substrate 11 via the embedded oxide film 13. The anti-vibration spring structure 25 is disposed on a periphery of the fixed portion 20 and connects the fixed portion 20 to the movable portion 30 and the beam portion 40. The anti-vibration spring structure 25 is released from the support substrate 11 because the embedded oxide film 13 on a back surface is removed. The movable portion 30 and the beam portion 40 form vibrators in the vibration angular velocity sensor. The movable portion 30 is released from the support substrate 11 because the embedded oxide film 13 on a back surface is removed. The beam portion 40 supports the movable portion 30 and also causes the movable portion 30 to undergo displacement in an x-axis direction and a y-axis direction for an angular velocity detection. Specific structures of the fixed portion 20, the movable portion 30, and the beam portion 40 will be described.

The fixed portion 20 is a portion which not only supports the movable portion 30, but is also provided with driving voltage application pads and detection signal extraction pads used for an angular velocity detection, neither of which are shown in the drawings. In the present embodiment, the respective functions specified above are realized by the single fixed portion 20. However, the functions may be allocated to, for example, a support fixed portion to support the movable portion 30, a driving fixed portion to which a driving voltage is applied, and a detection fixed portion used for an angular velocity detection. In such a case, for example, the fixed portion 20 shown in FIG. 1 may be used as the support fixed portion, and the driving fixed portion and the detection fixed portion may be connected to the support fixed portion. Also, the driving voltage application pads may be provided to the driving fixed portion and the detection signal extraction pads may be provided to the detection fixed portion.

More specifically, the fixed portion 20 has a structure in which a shape of a top surface is, for example, a rectangular shape and spring portions 25a of the anti-vibration spring structure 25 described below are connected at respective corners. The embedded oxide film 13 is left in a lower part of the fixed portion 20. Hence, the fixed portion 20 is fixed to the support substrate 11 via the embedded oxide film 13.

The anti-vibration spring structure 25 has the spring portions 25a and a frame portion 25b. The spring portions 25a are extended in four directions centered at the fixed portion 20, to be more specific, extended radially from four corners of the fixed portion 20, in other words, extended diagonally with respect to the x axis and the y axis. A width of the respective spring portions 25a (a dimension in a direction perpendicular to a longitudinal direction of the respective spring portions 25a) is smaller than a dimension in the z-axis direction to make it easier for the respective spring portions 25a to undergo displacement on the x-y plane. The frame portion 25b is of a rectangular frame shape surrounding the fixed portion 20 with the fixed portion 20 as a center and connected to the respective spring portions 25a inside the four corners. A width of respective sides of the frame portion 25b of a rectangular shape (a dimension in a direction perpendicular to a longitudinal direction of the respective sides) is smaller than a dimension in the z-axis direction to make it easier for the respective sides to undergo displacement on the x-y plane.

The movable portion 30 is a portion that undergoes displacement in response to an application of an angular velocity, and has driving weights which are caused to undergo driving vibrations upon application of a driving voltage and detection weights which are caused to vibrate according to an angular velocity upon application of the angular velocity during the driving vibrations. In the present embodiment, driving-detection weights 31 and 32 serving as both of driving weights and detection weights are provided as the movable portion 30. The driving-detection weights 31 and 32 are disposed on both sides in the x-axis direction with the fixed portion 20 in between and equally spaced apart from the fixed portion 20. The respective driving-detection weights 31 and 32 are formed in a same dimension (same mass). In the present embodiment, top surfaces of the respective driving-detection weights 31 and 32 have a rectangular shape. Each of the driving-detection weights 31 and 32 is connected to opposing two sides of driving beams 42 provided to the beam portion 40 and described below and is therefore supported at both ends. The respective driving-detection weights 31 and 32 are released from the support substrate 11 because the embedded oxide film 13 is removed in lower parts of the respective driving-detection weights 31 and 32. Hence, the respective driving-detection weights 31 and 32 are allowed to undergo driving vibrations in the x-axis direction by displacement of the driving beams 42. Upon application of an angular velocity, the respective driving-detection weights 31 and 32 are allowed to vibrate also in a rotation direction about the fixed portion 20 including the y-axis direction by displacement of the driving beams 42.

The beam portion 40 includes detection beams 41, the driving beams 42, and support members 43.

The detection beams 41 are linear beams extended in the y-axis direction and connecting the fixed portion 20 and the support members 43. In the present embodiment, the detection beams 41 are connected to opposing two sides of the frame portion 25b of the anti-vibration spring structure 25. Accordingly, the detection beams 41 connect the support members 43 to the fixed portion 20 via the anti-vibration spring structure 25. A dimension of the detection beams 41 in the x-axis direction is smaller than a dimension in the z-axis direction. The detection beams 41 are thus deformable in the x-axis direction.

The driving beams 42 are linear beams extended in the y-axis direction, that is, a direction parallel to the detection beams 41 and connecting the driving-detection weights 31 and 32 and the support members 43. Distances from the driving beams 42 provided to the respective driving-detection weights 31 and 32 to the detection beams 41 are equal. A dimension of the driving beams 42 in the x-axis direction is also smaller than the dimension in the z-axis direction. The driving beams 42 are thus deformable in the x-axis direction. Consequently, the driving-detection weights 31 and 32 are allowed to undergo displacement on the x-y plane.

The support members 43 are linear members extended in the x-axis direction. The detection beams 41 are connected to the support members 43 at center positions and the respective driving beams 42 are connected to the support member 43 at both ends. A dimension of the support members 43 in the y-axis direction is larger than dimensions of the detection beams 41 and the driving beams 42 in the x-axis direction. Hence, the driving beams 42 chiefly deform during driving vibrations and the detection beams 41 and the driving beams 42 chiefly deform upon application of an angular velocity.

The vibration angular velocity sensor formed according to the structure as above includes a frame body having a rectangular top surface and formed of the driving beams 42, the support members 43, and the driving-detection weights 31 and 32, and the detection beams 41 and the fixed portion 20 disposed inside the frame body.

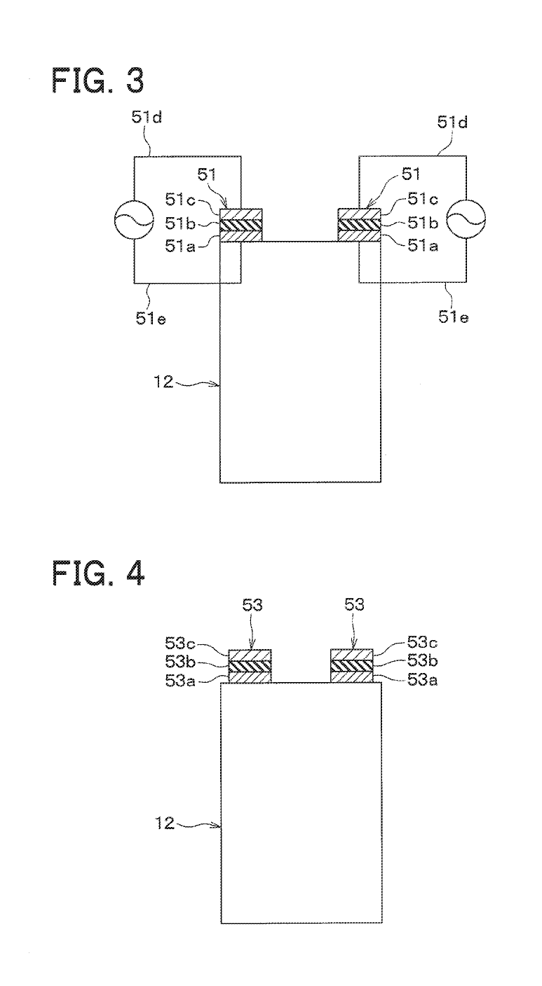

As is shown in FIG. 1 and FIG. 3, drive portions 51 are provided to the driving beams 42 and as is shown in FIG. 4, vibration detection portions 53 are provided to the detection beams 41. The vibration angular velocity sensor is driven when the drive portions 51 and the vibration detection portions 53 are electrically connected to an unillustrated control device provided outside. The vibration detection portions 53 function as detection elements.

As is shown in FIG. 1, the drive portions 51 are provided to the respective driving beams 42 near connection portions to the support members 43. Two drive portions 51 extended in the y-axis direction are provided to each location while being spaced apart by a predetermined distance. As is shown in FIG. 3, each drive portion 51 has a structure in which a lower electrode 51a, a driving thin film 51b, and an upper electrode 51c are sequentially layered on a surface of the semiconductor layer 12 forming the driving beams 42. The lower electrode 51a and the upper electrode 51c are formed of, for example, Al electrodes. The lower electrode 51a and the upper electrode 51c are connected to the unillustrated driving voltage application pads and unillustrated GND connection pads, respectively through wiring portions 51d, 51e extracted to the fixed portion 20 by way of the support portions 43 and the detection beams 41 shown in FIG. 1. The driving thin film 51b is formed of, for example, a film of lead zirconate titanate (PZT).

By generating a potential difference between the lower electrode 51a and the upper electrode 51c in the configuration as above, the driving thin film 51b sandwiched in between is displaced to cause the driving beams 42 to vibrate. Consequently, the driving-detection weights 31 and 32 are caused to undergo driving vibrations along the x-axis direction. For example, two drive portions 51 are provided to the respective driving beams 42, one on each end side in the x-axis direction. The driving thin film 51b of one drive portion 51 is displaced by compression stress while the driving thin film 51b of the other drive portion 51 is displaced by stretching stress. By repeating a voltage application as above on the respective drive portions 51 in turn, the driving-detection weights 31 and 32 are caused to undergo driving vibrations along the x-axis direction.

As are shown in FIG. 1 and FIG. 4, the vibration detection portions 53 are provided to the detection beams 41 near connection portions to the fixed portion 20. The vibration detection portions 53 extended in the y-axis direction are provided to the respective detection beams 41, one on each side in the x-axis direction. As is shown in FIG. 4, each vibration detection portion 53 has a structure in which a lower electrode 53a, a detection thin film 53b, and an upper electrode 53c are sequentially laminated on the surface of the semiconductor layer 12 forming the detection beams 41. The lower electrode 53a, the upper electrode 53c, and the detection thin film 53b are formed in a same manner, respectively, as the lower electrode 51a, the upper electrode 51c, and the driving thin film 51b forming the drive portion 51. The lower electrode 53a and the upper electrode 53c are connected to the unillustrated detection signal output pads, respectively through wiring portions 53d, 53e extracted to the fixed portion 20 shown in FIG. 1.

In the configuration as above, when the detection beams 41 undergo displacement upon application of an angular velocity, the detection thin film 53b deforms as the detection beams 41 undergoes displacement. Such a deformation gives rise to, for example, a variance in an electrical signal (a current value in the case of constant voltage driving and a voltage value in the case of constant current driving) between the lower electrode 53a and the upper electrode 53c. The variance is outputted as a detection signal indicating the angular velocity to an outside through the unillustrated detection signal output pads.

The above has described the configuration of the vibration angular velocity sensor of the present embodiment. An operation of the vibration angular velocity sensor configured as above will now be described.

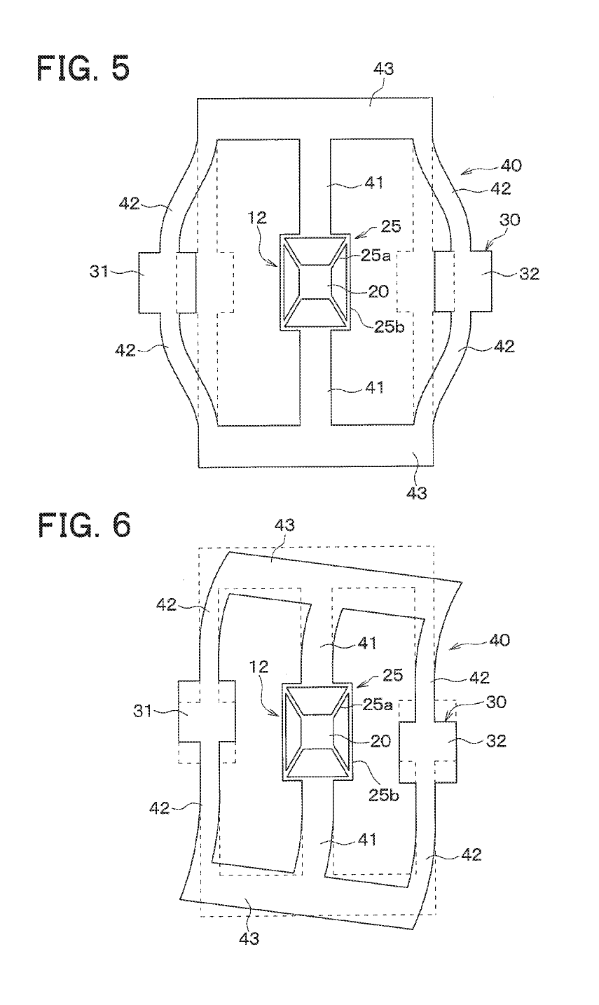

Firstly, as is shown in FIG. 3, a driving voltage is applied to the drive portions 51 provided to the driving beams 42. More specifically, by generating a potential difference between the lower electrode 51a and the upper electrode 51c, the driving thin film 51b sandwiched in between is displaced. Of two drive portions 51 provided side by side, the driving thin film 51b of one drive portion 51 is displaced by compression stress and the driving thin film 51b of the other drive portion 51 is displaced by stretching stress. By repeating a voltage application as above on the respective drive portions 51 in turn, the driving-detection weights 31 and 32 are caused to undergo driving vibrations along the x-axis direction. Consequently, as is shown in FIG. 5, a mode changes to a driving mode in which the driving-detection weights 31 and 32 supported at the both ends by the driving beams 42 are caused to move in directions opposite to each other along the x-axis direction with the fixed portion 20 in between. That is to say, a mode changes to a mode in which both of the driving-detection weights 31 and 32 come closer and move away from the fixed portion 20 repetitively.

When an angular velocity, that is, vibrations about the z-axis direction with the fixed portion 20 given as a center axis are applied to the vibration angular velocity sensor during driving vibrations as above, the mode changes to a detection mode in which, as is shown in FIG. 6, the driving-detection weights 31 and 32 vibrate also in a rotation direction about the fixed portion 20 including the y-axis direction. Accordingly, the detection beams 41 also undergo displacement and the detection thin films 53b provided to the vibration detection portions 53 deform as the detection beams 41 undergo displacement. Such a deformation gives rise to, for example, a variance in an electrical signal between the lower electrode 53a and the upper electrode 53c. The generated angular velocity can be detected when the electrical signal is inputted into an unillustrated control device or the like provided outside.

During the operation as above, an unwanted vibrations in the z-axis direction may be generated for some reason, for example, depending on presence or absence of vibrations (vehicle vibrations or the like) transmitted from a portion other than the vibration angular velocity sensor, misalignment of an axis orientation, asymmetrical machining, and a crystal fault.

In the present embodiment, however, the detection beams 41 and the driving beams 42 are connected using the support members 43 to form a frame shape together with the driving-detection weights 31 and 32. Hence, the structure thus obtained is same as a structure to support the detection beams 41 and the driving beams 42 at both ends. The structure as above is therefore capable of restricting an occurrence of an unwanted vibration mode in which tip ends of the detection beams 41 and tip ends of the driving beams 42 vibrate independently. For example, the structure as above is capable of restricting an occurrence of an unwanted vibration mode in which tip ends of two driving beams 42 on a side connected to the same support member 43 move in a same direction along the z-axis direction while the detection beams 41 are not vibrating in the z-axis direction. Also, the structure as above is capable of restricting an occurrence of an unwanted vibration mode in which tip ends of two driving beams 42 on a side connected to the same support member 43 move in opposite directions along the x-axis direction while the detection beams 41 are not vibrating in the z-axis direction. Further, the structure as above is capable of restricting an unwanted vibration mode in which tip ends of the detection beams 41 and tip ends of two driving beams 42 on a side connected to the same support member 43 move in different directions along the z-axis direction. Moreover, the structure as above is capable of restricting an unwanted vibration mode in which only one of two driving beams 42 move in the z-axis direction.

In the present embodiment, the anti-vibration spring structure 25 is provided to connection portions of the fixed portion 20 to the movable portion 30 and the beam portion 40. Owing to the structure as above, for example, in the case of an unwanted vibration mode in which a resonance frequency is lower than resonance frequencies of driving vibrations and detection vibrations (driving frequency and detection frequency, respectively) caused by an external impact, it is not the beam portion 40 but the anti-vibration spring structure 25 that chiefly deforms. Hence, deformation of the beam portion 40 can be restricted.

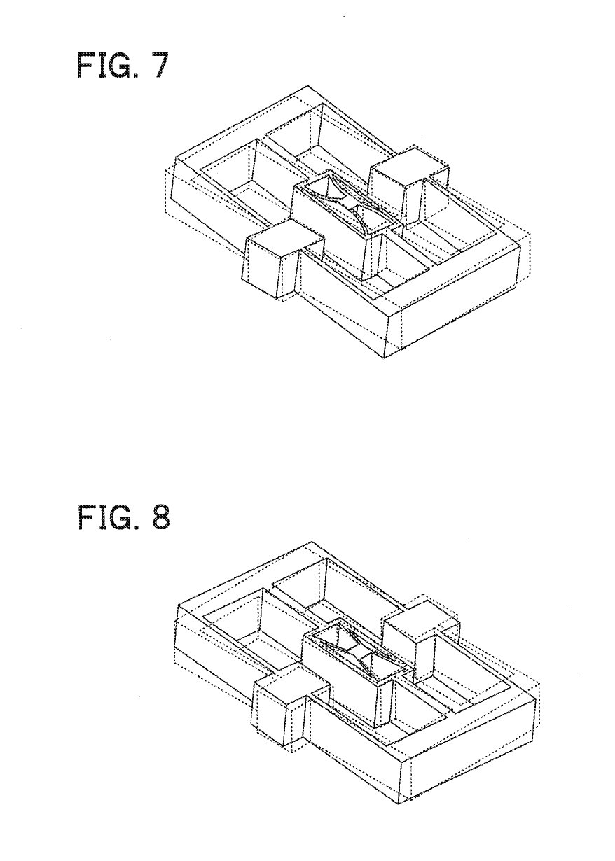

An unwanted vibration mode, for example, as is shown in FIG. 7 may possibly occur, in which one support member 43 and the other support member 43 move in opposite directions along the z-axis direction about the fixed portion 20 like a seesaw. In such a case, too, the anti-vibration spring structure 25 chiefly deforms and the detection beams 41 hardly deform. In the case of an unwanted vibration mode, for example, as is shown in FIG. 8, in which a frame structure formed of the movable portion 30 and the beam portion 40 is rotated on the x-y plane about the fixed portion 20, the anti-vibration spring structure 25 chiefly deforms and the detection beams 41 hardly deform.

As has been described, in the case of an unwanted vibration mode in which unwanted vibrations are generated at a frequency lower than a driving frequency during the driving vibrations in the driving mode or a detection frequency during detection vibrations in the detection mode, deformation of the beam portion 40 caused by the unwanted vibrations can be restricted. Consequently, detection accuracy can be enhanced and unwanted vibration modes such that deteriorate detection accuracy can be reduced.

When the anti-vibration spring structure 25 is disposed at a center support portion of the movable portion 30 and the beam portion 40 which form a frame structure, displacement of connection portions between the detection beams 41 and the anti-vibration spring structure 25 is increased by displacement of the anti-vibration spring structure 25 in comparison with a case where the detection beams 41 are directly connected to the fixed portion 20. Hence, when an angular velocity is applied, the angular velocity can be detected by the vibration detection portions 53 on the basis of larger deformation of the detection beams 41. Consequently, detection accuracy can be enhanced further.

### Second Embodiment

A second embodiment of the present disclosure will be described. The present embodiment is same as the first embodiment above except that a shape of a vibration angular velocity sensor is changed from the shape in the first embodiment above. The following will describe only a difference from the first embodiment above.

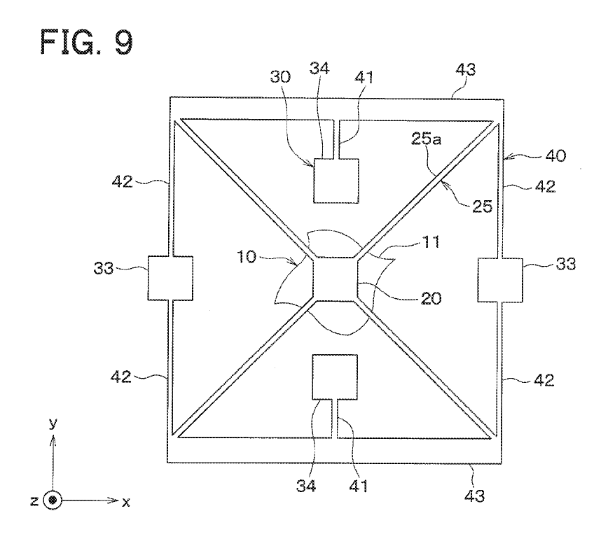

In the present embodiment, as is shown in FIG. 9, spring portions 25a of an anti-vibration spring structure 25 are extended along diagonal lines from four corners of a fixed portion 20 formed in, for example, a square shape. Also, a movable portion 30 has a structure in which drive weighs 33 and detection weights 34 are provided separately. Support members 43, driving beams 42, and the driving weights 33 together form a rectangular frame structure and the detection weights 34 are connected to the support members 43 at center positions via detection beams 43. The fixed portion 20 is disposed at a center position inside the rectangular frame structure formed of the support members 43, the driving beams 42, and the driving weights 33. The spring portions 25a are connected at four corners of the rectangular frame structure, that is, connection positions between the support members 43 and the driving beams 42. The frame structure is thus connected to the fixed portion 20. The spring portions 25a are extended diagonally with respect to an x axis and a y axis. The x axis is referred to also as a first axis and the y axis is referred to also as a second axis. Consequently, the rectangular frame structure formed of the support members 43, the driving beams 42, and the driving weights 33 is supported to the fixed portion 20 via the spring portions 25a. Further, the detection weights 34 are supported to the support members 43 via the detection beams 41.

In the structure as above, the driving weights 33 are disposed on both sides in one direction on a plane of a substrate 10 with the fixed portion 20 as a center and the detection weights 34 are disposed on both sides in a direction perpendicular to the one direction in which the driving weights 33 are disposed on the plane of the substrate 10. Also, the driving weights 33 are supported at both ends by disposing the driving beams 42 on both sides in one direction on the plane of the substrate 10 with the fixed portion 20 as a center. The support members 43 are disposed on both sides in another direction perpendicular to the one direction and the detection beams 41 are connected to the support members 43 at center positions. The detection weights 34 are thus supported to the support members 43.

A vibration angular velocity sensor of the present embodiment configured as above includes the movable portion 30 and a beam portion 40 which are supported via the anti-vibration spring structure 25 with the fixed portion 20 fixed to the substrate 10 as a center. In the vibration angular velocity sensor configured as above, when the driving weights 33 disposed on both sides of the fixed portion 20 are caused to undergo driving vibrations in directions opposite to each other about the fixed portion 20, the detection weights 34 vibrate in a direction perpendicular to vibration directions of the driving weights 33 on the plane of the substrate 10 upon application of an angular velocity. The angular velocity can be detected on the basis of vibrations of the detection weights 34.

Even when the vibration angular velocity sensor is configured as above, effects same as the effects of the first embodiment above can be obtained due to the anti-vibration spring structure 25 disposed between the fixed portion 20 and the beam portion 40 formed of the support members 43, the driving beams 42, and the detection beams 41 and between the fixed portion 20 and the movable portion 30 formed of the driving weights 33 and the detection weights 34. More specifically, for example, in the case of an unwanted vibration mode in which a resonance frequency is lower than resonance frequencies of driving vibrations and detection vibrations (driving frequency and detection frequency, respectively) caused by an external impact, it is not the beam portion 40 but the anti-vibration spring structure 25 that chiefly deforms. Hence, deformation of the beam portion 40 can be restricted. Consequently, effects same as the effect of the first embodiment above can be obtained.

Also, in the case of the configuration as above, the vibration angular velocity sensor has a structure, in which the movable portion 30 and the beam portion 40 are provided outside the anti-vibration spring structure 25. In the structure as above, the detection beams 41 are remote from the anti-vibration spring structure 25. Accordingly, a resonance frequency of detection vibrations (detection resonance frequency) becomes unsusceptible to the anti-vibration spring structure 25. It thus becomes easier to arrange resonances, for example, in such a manner that the detection resonance frequency becomes higher than an anti-vibration mode resonance frequency, that is, a resonance frequency in an unwanted vibration mode (anti-vibration mode resonance frequency<detection resonance frequency).

### Modification of Second Embodiment

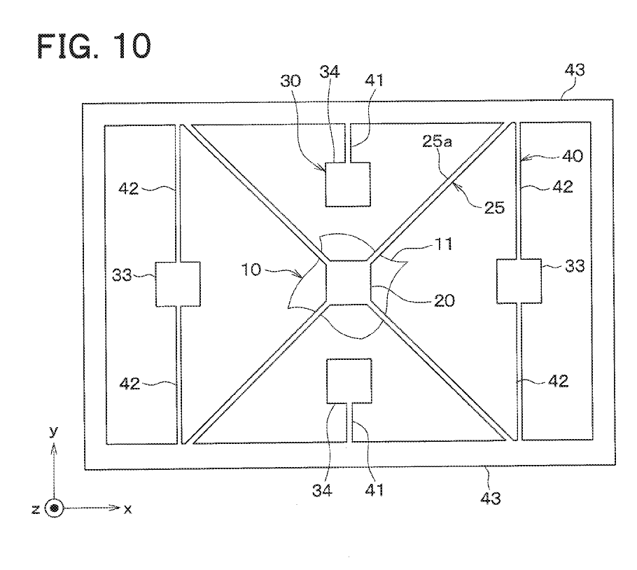

In the second embodiment above, the support members 43, the driving beams 42, and the driving weights 33 together form the rectangular frame structure. Alternatively, the support members 43 may form an outer frame structure, for example, a rectangular frame structure as is shown in FIG. 10 and the support members 43, the driving beams 42, and the driving weights 33 may together form an inner frame structure inside the outer frame structure. In short, the structure may be modified in such a manner that the driving weights 33 are supported to the support members 43 forming the outer frame structure via the driving beams 42. When configured in such a manner, because an outer wall of the vibration angular velocity sensor can be formed by the support members 43, strength of the vibration angular velocity sensor can be increased further.

### Other Embodiments

In the respective embodiments above, for instance, the detection element forming the vibration detection portion 53 has a structure using a piezoelectric film same as a piezoelectric film used in the drive portion 51. However, the detection element is not limited to detection elements having a structure using the piezoelectric film and any other detection elements capable of extracting displacement of detection beams 41 in the form of an electrical signal can be used as well. For example, a piezoresistance (gauge resistance) may be formed in a semiconductor layer 12 forming the detection beams 41 to use the piezoresistance as the detection element. The piezoresistance may be, for example, a p⁺-type layer or an n⁺-type layer provided on a surface layer of the semiconductor layer 12.

The respective embodiments above adopt piezoelectric driving using a piezoelectric function, by which the driving beams 42 are caused to vibrate by displacing the driving thin film 51b sandwiched between the lower electrode 51a and the upper electrode 51c with a potential difference generated between the two electrodes 51a and 51c. Also, the respective embodiments above adopt a piezoelectric detection using a piezoelectric effect, by which deformation of the detection thin film 53b in association with displacement of the detection beams 41 upon application of an angular velocity is extracted in the form of an electrical signal between the lower electrode 53a and the upper electrode 53c. In short, the vibration angular velocity sensors described in the respective embodiments above are piezoelectrically-driven and perform a piezoelectric detection.

Alternatively, the vibration angular velocity sensor may be piezoelectrically-driven and perform an electrostatic detection. For example, electrode portions forming an electrostatic capacitance may be provided to detection beams 41 and adjacent portions to detect an angular velocity on the basis of a variance in electrostatic capacitance. The electrostatic capacitances may be provided to portions other than the detection beams 41 and adjacent portions. For example, an electrostatic capacitance may be formed by providing the electrode portions at both ends of support members 43 and adjacent portions.

Further, comb-teeth electrodes may be provided to detection beams 41 and capacitive sensors as a detection fixed portion provided with comb-teeth electrodes opposing the comb-teeth electrodes provided to the detection beams 41 may be used as detection elements to extract a variance in capacitance formed between the respective comb-teeth electrodes in the form of an electrical signal

The embodiments above have a structure in which the drive portions 51 and the vibration detection portions 53 are provided, respectively, to the driving beams 42 and the detection beams 41 only near the support members 43. It should be appreciated, however, that the structure described above is a mere example and, for example, drive portions 51 and vibration detection portions 53 may be provided, respectively to driving beams 42 and the detection beams 41 entirely.

In the embodiments above, an outer shape of the frame structure formed of the movable portion 30 and the beam portion 40 and an outer shape of the anti-vibration spring structure 25 are a rectangular shape. However, the outer shapes are not necessarily a rectangular shape. For example, the frame structure formed of the movable portion 30 and the beam portion 40 only has to have a line-symmetrical structure with respect to the detection beams 41 (center line) and also a point-symmetrical structure with respect to the fixed portion 20. Accordingly, the support members 43 may be shaped so as to cross the detection beams 41 diagonally instead of crossing the detection beams 41 perpendicularly. Further, the support members 43 may be of an inclined shape.

1. A vibration angular velocity sensor comprising:
a fixed portion fixed to a substrate;
a movable portion having driving-detection weights disposed on both sides of a first axis along one direction on a plane of the substrate with the fixed portion as a center to serve as both a driving weight and a detection weight;
a beam portion having detection beams supported to the fixed portion and extended on both sides of a second axis perpendicular to the first axis on the plane of the substrate with the fixed portion as a center, support members disposed to tip ends of the detection beams on an opposite side from the fixed portion so as to cross the detection beams, and driving beams supported to the support members and disposed on both sides of the first axis with the detection beams in between to support the driving-detection weights at both ends, and having a frame structure formed of the driving beams, the support members, and the driving-detection weights; and
an anti-vibration spring structure disposed between the detection beams and the fixed portion and being deformable along the first axis and the second axis,
wherein the vibration angular velocity sensor causes the driving-detection weights disposed on the both sides of the fixed portion to undergo driving vibrations in directions opposite to each other along the first axis about the fixed portion and detects an angular velocity based on a fact that the driving-detection weights vibrate also along the second axis on the plane of the substrate upon application of the angular velocity.

2. The vibration angular velocity sensor according to claim 1, further comprising:
drive portions disposed to the driving beams and each including a driving thin film formed of a piezoelectric film which causes the driving-detection weights to undergo driving vibrations; and
detection elements disposed to the detection beams and detecting displacement of the detection beams upon application of the angular velocity.

3. The vibration angular velocity sensor according to claim 1, wherein
the anti-vibration spring structure has spring portions extended in four directions diagonally with respect to both of the first axis and the second axis centered at the fixed portion, and a frame portion of a rectangular frame shape surrounding the fixed portion and connected to the respective spring portions inside four corners, and
the detection beams are connected to opposing two sides of the frame portion.

4. The vibration angular velocity sensor according to claim 1, wherein
the anti-vibration spring structure deforms more readily than the detection beams at a resonance frequency lower than a driving frequency which is a resonance frequency when the driving-detection weights are caused to undergo driving vibrations and a detection frequency which is a resonance frequency when the driving-detection weights undergo detection vibration upon application of the angular velocity.

5. A vibration angular velocity sensor comprising:
a fixed portion fixed to a substrate;
a movable portion having driving weights disposed on both sides of a first axis along one direction on a plane of the substrate with the fixed portion as a center and detection weights disposed on both sides of a second axis perpendicular to the first axis on the plane of the substrate;
a beam portion having driving beams disposed on both sides of the first axis with the fixed portion as a center to support the driving weights at both ends, support members disposed on both sides of the second axis and to which the driving beams are connected, and detection beams connected to center positions of the supporting members and supporting the detection weights, and having a frame structure formed of the support members, the driving beams, and the driving weights; and
an anti-vibration spring structure connecting the beam portion and the fixed portion and being deformable along the first axis and the second axis,
wherein the vibration angular velocity sensor causes the driving weights disposed on the both sides of the fixed portion to undergo driving vibrations in directions opposite to each other along the first axis about the fixed portion and detects an angular velocity based on a fact that the detection weights vibrate also along the second axis on the plane of the substrate upon application of the angular velocity.

6. The vibration angular velocity sensor according to claim 5, wherein
the anti-vibration spring structure has spring portions extended in four directions diagonally with respect to both of the first axis and the second axis centered at the fixed portion, and
the beam portion and the movable portion are supported to the fixed portion via the spring portions by connecting the spring portions to connection positions between the support members and the driving beams which form the frame structure.

7. The vibration angular velocity sensor according to claim 6, wherein
the support member has a frame shape and forms an outer frame structure, and
the driving beams and the driving weights are supported by the support member to form an inner frame structure by the support member, the driving beams, and the driving weights.

8. The vibration angular velocity sensor according to claim 5, wherein
the anti-vibration spring structure deforms more readily than the detection beams at a resonance frequency lower than a driving frequency which is a resonance frequency when the driving weights are caused to undergo driving vibrations and a detection frequency which is a resonance frequency when the detection weights undergo detection vibrations upon application of the angular velocity.
